(19) United States
(12) Patent Application Publication
(10) Pub. No.: US 2012/0175677 A1
(43) Pub. Date: Jul. 12, 2012

(54) PHOTOCELL

(75) Inventors: Neil Thomson Gordon, Malvern (GB); Timothy Ashley, Malvern (GB)

(73) Assignee: QINETIQ LIMITED, Farnborough, Hampshire (GB)

(21) Appl. No.: 13/496,362

(22) PCT Filed: Sep. 21, 2010
(86) PCT No.: PCT/GB2010/001763

§ 371 Date: Mar. 15, 2012

(30) Foreign Application Priority Data
Sep. 22, 2009 (GB) 0916589.5

(51) Int. Cl. H01L 31/109; H01L 31/0352

(52) U.S. Cl. 257/184; 257/436; 257/E31.067; 257/E31.037

(57) ABSTRACT

A photocell which operates at multiple wavelengths for efficient power generation from broadband incident radiation. According to a preferred embodiment, the photocell is a multi-layer device that includes a first outer layer, a middle layer and an inner layer disposed on a substrate. All three layers are formed from II-VI semiconductor layers. The device is arranged such that the outer layer has a high band gap, the middle layer has a band gap which is less than half the band gap of the outer layer and the inner layer has a band gap which is less than half that of the substrate. Thus, there is a step change in band gap between various layers.

This invention relates to a photocell cell, that is an apparatus for converting incident optical radiation to electrical energy and in particular to a photocell which operates at multiple wavelengths for efficient power generation from broadband incident radiation such as the solar flux or a thermo-photovoltaic converters which uses other hot sources to generate electrical power.

Photocells, often referred to as solar cells, are well known for providing electrical energies from incident optical radiation, in particular sunlight.

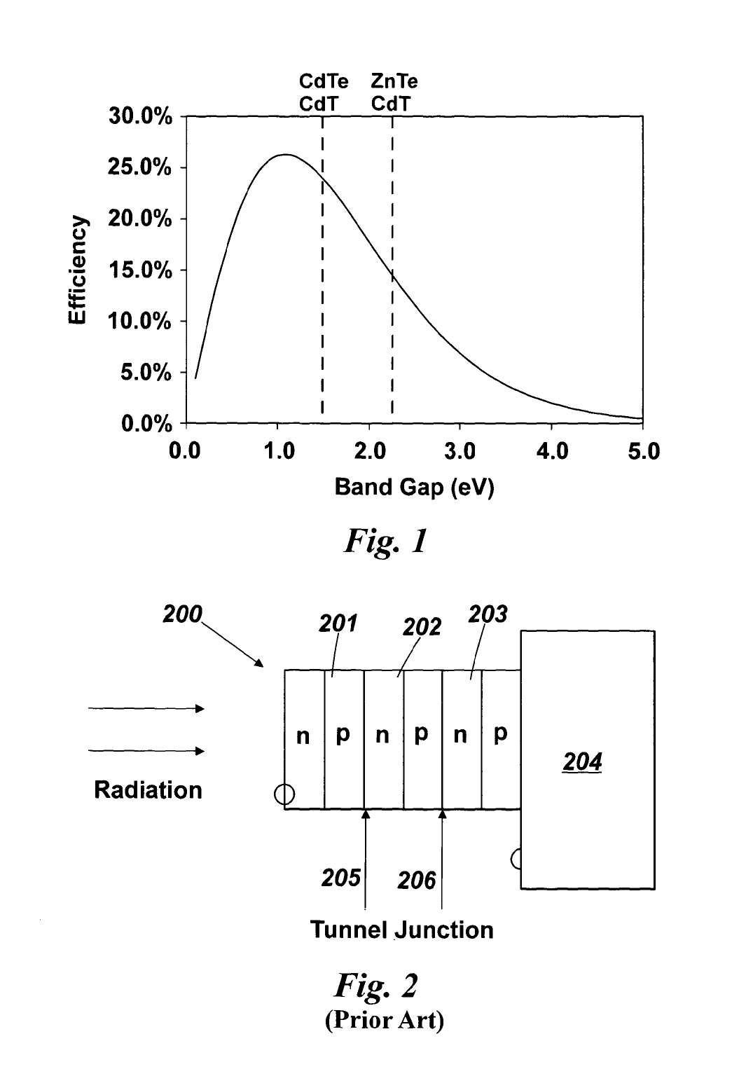

A well known photocell uses a semiconductor p-n junction arrangement. The conversion of optical energy into electrical energy using such a solar cell is most efficient for photon energies slightly above the band gap of the semiconductor material used. If the photon energy is less than the band gap it is not absorbed and if it is significantly larger than the band gap, the excess energy (above the band gap) will be wasted as heat. For photocells designed to work with a single wavelength of illuminating radiation the band gap can be matched to the wavelength of the source. However the spectrum of solar radiation extends over a range of wavelengths from about 0.3 μm to 5 μm. FIG. 1 shows the estimated efficiency of a single junction photocell for incident radiation from a black body at 5800K (approximately the surface temperature of the sun). It can be seen that there is a maximum theoretical efficiency of about 26% Cadmium Telluride (CdTe) has a band gap which is close to this peak and offers a theoretical 24% efficiency and it would be possible to fabricate a Mercury Cadmium Telluride (HgCdTe) photocell with a band gap which is optimised for the peak theoretical efficiency.

In order to increase efficiency photocells have been made consisting of several junctions in series stacked vertically. Each junction has a different band gap and so is tuned to a different wavelength of radiation. The junctions are arranged such that the detector junction with the largest band gap is outermost. Radiation with the highest energy is absorbed by this outermost detector junction and radiation with energies below the band gap is transmitted through to be absorbed by a lower detector junction.

In order for the individual p-n junctions to operate as separate junctions the interface between the p-n junctions are arranged to be tunnel junctions as shown in FIG. 2. This generally requires very high doping levels (of greater than 1×10¹⁸ cm⁻³) with a step change in doping profile across the tunnel junction. Multiple junction devices with two or three junctions have been reported in III-V semiconductor systems and have shown increased efficiency as compared to a single detector approach. See for example Nasser H. Karam, Richard R. King, B. Terence Cavicchi, Dimitri D. Krut, James H. Ermer, Moran Haddad, Li Cai, David E. Joslin, Mark Takahashi, Jack W. Eldredge, Warren T. Nishikawa, David R. Lillington, Brian M. Keyes, Richard K. Ahrenkiel, IEEE TRANSACTIONS ON ELECTRON DEVICES, 46(10), (1999).

Whilst such a multiple junction approach is achievable with III-V semiconductor systems such as Gallium Arsenide it is not feasible with II-VI semiconductors such as CdTe or HgCdTe which have band gaps that are better suited to the solar radiation. Group II-VI materials have high interdiffusion constants and thus it is not possible to achieve a doping profile which has the required spatial variation to form effective tunnel junctions.

It is therefore an object of the present invention to provide an improved photocell.

Thus according to the present invention there is provided a photocell comprising at least an outermost first layer of semiconductor material and an inner second layer of semiconductor material wherein the second layer of semiconductor material has a band gap which is lower than the band gap of the first layer of semiconductor material such that carriers crossing from the first layer to the second layer cause impact ionisation.

As the skilled person will be well aware impact ionisation is an Auger process, effectively the opposite of Auger recombination. Impact ionisation occurs when an electron with kinetic energy above the band gap of a semiconductor material transfers its energy to ionise another electron into the conduction band, thus creating an additional electron-hole pair. The original electron remains in the conduction band and thus the effective current is doubled.

It is known to use the Auger process in an avalanche photo-detector. In such devices, a voltage (or bias) is typically applied to generate gain due to impact ionisation. However, an avalanche photo-detector such as that disclosed in GB 2115610 A to Capasso et a/would not function as a solar cell when illuminated with radiation, because potential barriers exist in the semiconductor material at zero applied bias.

The device of the present invention has an outermost first layer of semiconductor material which has a band gap which is greater than the band gap of a second inner layer of semiconductor material. Photons with high enough energy are absorbed in the outermost first layer and create electron-hole pairs. Depending on the nature of the device one type of carrier will diffuse to the boundary between the first and second layers where there is a change in the band gap. Carriers crossing this boundary can have sufficient kinetic energy to create an additional electron hole pair in the second layer, thus doubling the photocurrent. In addition photons which were not absorbed in the first layer but which have energies above the band gap of the second layer will be absorbed in the second layer.

The device of the present invention thus has several advantages. It uses a multilayered structure to efficiently extract radiation from photons at a range of wavelengths as is taught in the multi-junction approach but does not require the presence of tunnel junctions. Thus the present invention may be implemented using II-VI materials. Efficient Auger processes are found in II-VI semiconductors, i.e. these materials exhibit relatively high Auger coefficients, and thus II-VI materials are particularly suitable for use in the present invention. Thus the first semiconductor layer may be a II-VI semiconductor layer and the second semiconductor layer may be a II-VI semiconductor layer.

The present invention also provides current gain in the transition from the first semiconductor layer to the second semiconductor layer, albeit with a reduction in photovoltage. This allows for extraction of a high photocurrent. The photocell of the present invention therefore offers current addition—along with multiplication at the transition between the first and second layer. In some applications however where a higher photovoltage is desired the invention may provide a photoelectric apparatus comprising a plurality of photocells, the photocell being linked in series in order to increase the photovoltage generated.

In the multi-junction approach, the equivalent circuit of the device consists of a number of single-junction cells connected in series. This means that the current generated in each cell goes through the series resistance of all the other cells and this reduces the efficiency of the combined unit. The present invention does not suffer from this because the currents are combined into a single junction.

Electrons entering the second layer of semiconductor material need to have sufficient thermal energy to cause impact ionisation. Due to the large difference in effective mass between electrons and holes in these materials, the threshold energy for impact ionisation is close to the band gap energy. Hence the band gap of the second layer of semiconductor material needs to be less than 50% of the band gap of the first layer of semiconductor material. A band gap reduction between the first layer and second layer of greater than 50% allows carriers produced in the first layer which diffuse to the second layer to have sufficient energy to cause impact ionisation.

The photocell may have additional layers of semiconductor material arranged as inner layers and be arranged such that the band gap of each semiconductor layer is less than the band gap of its adjacent outer layer. As used in this specification the terms outermost, outer, innermost and inner as used in relation to the photocell refer to the order in which the layers would be encountered by incident radiation in use. Thus the outermost layer, i.e. the first layer of semiconductor material is the layer which is first encountered by incident radiation in use. Thus were the device to have a third layer of semiconductor material this third layer would be inward of the first and second layers and the band gap of the third layer would be less than that of it's adjacent layer on the outward side, i.e. the second layer.

A photocell of the present invention incorporating multiple layers is thus arranged so that radiation passing through the device encounters layers of progressively reducing band gap. The band gap of each layer of semiconductor material may be arranged to be 50% or less of the band gap of its adjacent outer layer.

As is conventional for a photocell, the photocell of the invention is typically operated at zero or near zero bias.

The choice of semiconductor material for the first and second layers will be based on various criteria including the intended use (and hence spectrum of illuminating radiation), cost and ease of manufacturing. The semiconductor layers may comprise layers of the same material systems in different compositions—for instance two or more layers could comprise Mercury Cadmium Telluride layers with different compositions. Additionally or alternatively at least one semiconductor layer may comprise a different material system to another semiconductor layer with the layers chosen from materials such as Cadmium Telluride, Zinc Telluride and Mercury Cadmium Telluride. In one embodiment the outer layer could comprise Zinc Telluride and the inner layer an appropriate composition of Mercury Cadmium Telluride. The skilled person will be aware that when using layers of different material compositions lattice matching will be an issue and thus the choice of material system will include not only band gap considerations but also manufacturing constraints and the effect of lattice mismatch.

Preferably, the semiconductor material is a bulk semiconductor material. For some bulk semiconductor materials, carrier multiplication can be inefficient. However, this does not apply to bulk Cadmium Telluride, Zinc Telluride and Mercury Cadmium Telluride, and more particularly to bulk Mercury Cadmium Telluride, because there is a large asymmetry between the effective masses in the conduction bands (reference: “Properties of Narrow Gap Cadmium-based Compounds”, Ed. Peter Capper, EMIS DATA REVIEW SERIES No. 10, INSPEC, Institution of Electrical Engineers, London, 1994). Accordingly, those bulk materials are particularly preferred for the photocell of the invention.

The skilled person will understand what semiconductor materials are suitable II-VI material and will understand that II-VI semiconductors also include the oxides, sulphides and selenides and Mn and Mg compounds. Sulphides and selenides are also used in solar cells. Crystal type (i.e. zinc blende or wurtzite) also needs to be taken into consideration with some of the possible combinations.

In another aspect of the present invention there is provided a photocell comprising a plurality of layers, each layer being arranged to absorb photons having a lower energy than its adjacent layer on the outward side and adapted such that, in use, carriers generated in each layer cause impact ionisation in the adjacent layer on the inward side.

In a variant of the present invention the band gap may vary continuously between layers such that the boundary between layers represents a continuum of band gaps rather than a step change in band gap between layers as in the first embodiment of the invention. In this embodiment carriers generated by photon absorption which move inward through the device would cause ionisation at different parts of the device depending on the energy of the particular carrier and the variation in band gap. This would allow carriers to ionise as soon as possible which could improve efficiency.

The invention will now be described by way of example only with respect to the following drawings, of which:

FIG. 1 shows the theoretical efficiency obtainable from a single junction device photocell illuminated by radiation from a black body at 5800K,

FIG. 2 shows a prior art multiple junction photocell,

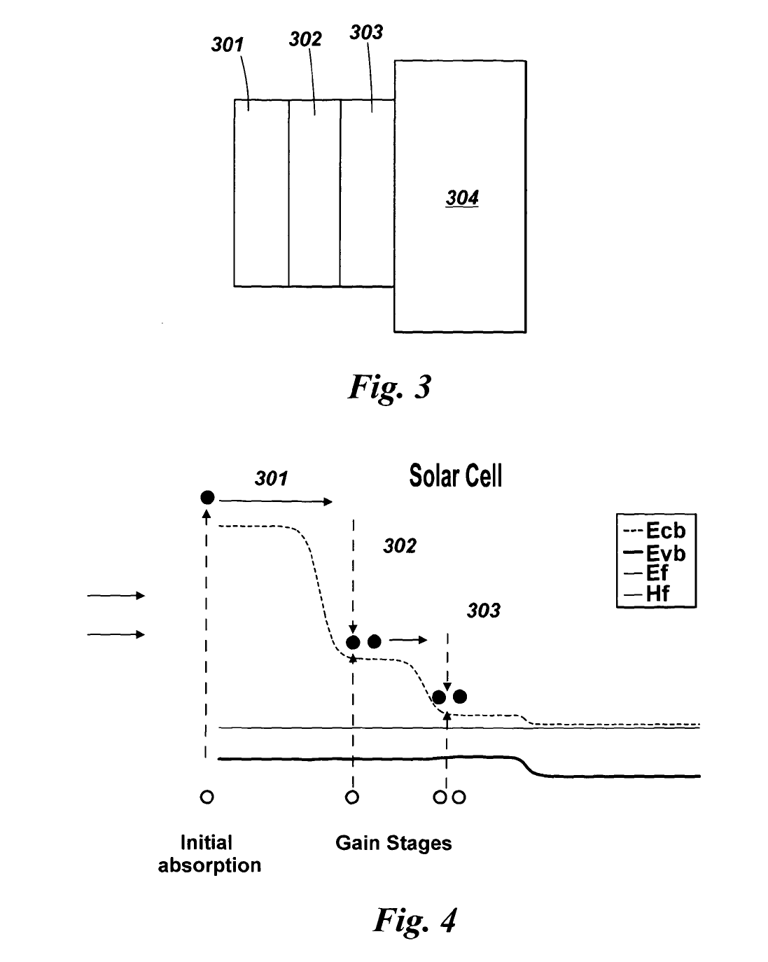

FIG. 3 shows a device according to the present invention, and

FIG. 4 shows the energy bands of a device according to the present invention.

FIG. 1 shows the theoretical efficiency of a single photocell against band gap for a single junction photocell device for a black body at 5800K, which is approximately the surface temperature of the sun. Thus FIG. 1 illustrates the theoretical efficiency which can be achieved by a single junction photocell illuminated with solar radiation. It can be seen that the peak efficiency achievable with a junction with an optimised band gap is about 26%. The band gaps of cadmium telluride (CdTe) and zinc telluride (ZnTe) are also illustrated and it can be seen that CdTe is quite close to optimal efficiency and offers around a 24% theoretical efficiency.

The reason that the theoretical efficiency is relatively low is that solar radiation comprises photons at a range of wavelengths and hence a range of energies. Photons having energy below the band gap of the junction will not be absorbed and for photons with energies significantly above the band gap the excess energy will generally be wasted as heat.

FIG. 2 shows a prior art multi-junction photocell 200. This device has three separate p-n junctions 201, 202, 203 disposed on a substrate 204. Each junction has a different band gap, with the outermost junction 201 having the largest band gap and the middle junction 202 having a larger band gap than the innermost junction 203. In use the device receives incident radiation and high energy photons with energies above the band gap of junction 201 create electron-hole pairs in this first junction. Photons with energies below the band gap of junction 201 but above the band gap of junction 202 pass through junction 201 and are absorbed in junction 202. Photons having energies lower than the band gap of the second junction 202 will pass through both the first and second junctions 201 and 202 and may be absorbed by junction 203 with the lowest band gap.

Junctions 201, 202, 203 are connected in series and hence to allow the photocurrent generated in the outer junctions 201 and 202 to flow through the inner junction(s) the interfaces between p-n junctions are arranged as tunnel junctions 205, 206. This allows the photocurrent to tunnel through the interfaces and be usefully extracted. This requires a high doping level, of greater than 1×10¹⁸ cm⁻³, and a change in doping level on a small length scale, i.e. a steep change in doping profile. This is achievable with III-V semiconductor materials such as gallium arsenide but does not appear possible with II-VI materials such as CdTe or ZnTe due to the high interdiffusion constants in II-VI materials.

A photocell 300 according to the present invention is shown in FIG. 3. This device is a multi-layer device with a first outer layer 301, a middle layer 302 and an inner layer 303 disposed on a substrate 304. All three layers are formed from II-VI semiconductor layers. The device is arranged such that layer 301 has a high band gap, layer 302 has a band gap which is less than half the band gap of layer 301 and layer 303 has a band gap which is less than half that of layer 304. Thus there is a step change in band gap between the various layers. FIG. 4 illustrates the energy diagram for such a device.

In use incident radiation is received by the device. High energy photons, with energies above the band gap of layer 301 create electron hole pairs in layer 301. Photons with lower energies will pass through layer 301 into layer 302 where, if they have sufficient energy, they will create an electron-hole pair in layer 302 or otherwise pass through to layer 303.

The layers 301, 302, 303 are electrically connected in series and hence carriers (electrons or hole depending on the nature of the device) created in layer 301 will diffuse to layer 302. The carriers, e.g. electrons, crossing from layer 301 to 302 have sufficient energy to create an additional electron-hole pair in layer 302 through impact ionisation. Thus there is current gain. Carriers present in layer 302, which may be due to photon absorption in layer 302 or the photon current generated from carriers crossing from layer 301, then diffuse to layer 303 where additional impact ionisation occurs.

Thus at the crossing between an outer layer and the next inner layer the photo-current is approximately doubled, assuming a high Auger process efficiency, and the photovoltage is halved (as the inner layer has a lower band gap).

The photocell of the present invention avoids the need for tunnel junctions and can be fabricated using relatively simple fabrication technology. It uses the high Auger coefficients exhibited by II-VI materials to advantage. Further accurate current matching, required for a conventional device such as shown in FIG. 2, is not required leading to greater design flexibility.

The device may be fabricated from any suitable materials, especially II-VI semiconductor materials. For instance the layers could comprise CdTe or ZnTe or HgCdTe.

The first layer 301 could therefore be CdTe or ZnTe. The efficiency of the first layer considered on its own is the basic efficiency as illustrated in FIG. 1. Thus the efficiency is approximately 24% for a first layer 301 of CdTe and 14.5% for a first layer of ZnTe. The second layer 302 has a band gap of approximately 50% or less of the first layer 301 to ensure that electrons (or holes depending on the device design) crossing to the second layer 302 have sufficient energy for impact ionisation. Thus the band gap for the second layer would be approximately 0.7 eV for a first layer of CdTe and 1.0 eV for first layer of ZnTe. The second layer thus has a normal photo-generation efficiency of 12% for CdTe and 19.9% for ZnTe.

For the purposes of illustration if one assumes that the impact ionisation is 100% efficient then the total efficiency for the two layers is 36% for CdTe and 34.2% for ZnTe. Using the same assumptions the total efficiency for the three layer device shown in FIGS. 3 and 4 would be 39.7% for CdTe and 38.6% for ZnTe. The present invention therefore offers significant efficiency improvements.

1. A photocell comprising at least an outermost first layer of semiconductor material and an inner second layer of semiconductor material wherein the second layer of semiconductor material has a band gap which is lower than the band gap of the first layer of semiconductor material such that carriers crossing from the first layer to the second layer cause impact ionisation.

2. A photocell as claimed in claim 1 wherein the first semiconductor layer comprises a II-VI semiconductor layer.

3. A photocell as claimed in claim 1 wherein the second semiconductor layer comprises a II-VI semiconductor layer.

4. A photocell as claimed in claim 1 wherein the band gap of the second layer of semiconductor material is less than 50% of the band gap of the first layer.

5. A photocell as claimed in claim 1 further comprising at least one additional layer of semiconductor material arranged as inner layers wherein the band gap of each semiconductor layer is less than the band gap of its adjacent outer layer.

6. A photocell as claimed in claim 5 wherein the band gap of each layer of semiconductor material is less than 50% of the band gap of its adjacent outer layer.

7. A photocell as claimed in claim 5 wherein the or each additional semiconductor material comprises a II-VI semiconductor material.

8. A photocell as claimed in claim 1 wherein at least one semiconductor layer comprises a layer of the same material system as another semiconductor layer but in different compositions.

9. A photocell as claimed in claim 1 wherein at least one semiconductor layer may comprise a different material system to another semiconductor layer.

10. A photocell as claimed claim 1 wherein at least one semiconductor layer comprises Mercury Cadmium Telluride.

11. A photocell as claimed in claim 1 wherein at least one semiconductor layer comprises Cadmium Telluride

12. A photocell as claimed in claim 1 wherein at least one semiconductor layer comprises Zinc Telluride.

13. A photocell as claimed in claim 1 wherein the band gap may varies continuously between layers.

14. A photocell as claimed in claim 1, wherein the semiconductor material is a bulk semiconductor.

15. A photocell according to claim 1 operated at zero bias.

16. A photocell comprising a plurality of layers, each layer being arranged to absorb photons having a lower energy than its adjacent layer on the outward side and adapted such that, in use, carriers generated in each layer cause impact ionisation in the adjacent layer on the inward side.
